(19) United States
(12) Patent Application Publication
(10) Pub. No.: US 2013/0043599 A1
(43) Pub. Date: Feb. 21, 2013

(54) CHIP PACKAGE PROCESS AND CHIP PACKAGE STRUCTURE

(71) Applicants: Yu-Wei Huang, Taichung City (TW); Yin-Po Hung, Kaohsiung City (TW); Tao-Chih Chang, Taoyuan County (TW); Jing-Yao Chang, New Taipei City (TW); Shin-Yi Huang, Taichung City (TW); Ren-Shin Cheng, Tainan City (TW)

(72) Inventors: Yu-Wei Huang, Taichung City (TW); Yin-Po Hung, Kaohsiung City (TW); Tao-Chih Chang, Taoyuan County (TW); Jing-Yao Chang, New Taipei City (TW); Shin-Yi Huang, Taichung City (TW); Ren-Shin Cheng, Tainan City (TW)

(73) Assignee: INDUSTRIAL TECHNOLOGY RESEARCH INSTITUTE, Hsinchu (TW)

(21) Appl. No.: 13/344,575

(22) Filed: Jan. 5, 2012

(30) Foreign Application Priority Data
Aug. 15, 2011 (TW) 100129094

(51) Int. Cl. H01L 21/58; H01L 23/48

(52) U.S. Cl. 257/774; 438/107; 257/E23.011; 257/E21.505

(57) ABSTRACT

Chip package processes and chip package structures are provided. The chip package structure includes a substrate, a chip, an insulating layer, a third patterned conductive layer and an electronic element. The substrate has a first patterned conductive layer. The chip is disposed on the substrate. A second patterned conductive layer of the chip is bonded to the first patterned conductive layer of the substrate. The chip has a first through hole. The insulating layer is disposed on the chip and filled into the first through hole. The insulating layer has a second through hole which passes through the first through hole. The third patterned conductive layer is disposed on the insulating layer and filled into the second through hole to electrically connect to the first patterned conductive layer. The electronic element is disposed on the third patterned conductive layer and electrically connects to the third patterned conductive layer.

### CROSS-REFERENCE TO RELATED APPLICATION

This application claims the priority benefit of Taiwan application serial no. 100129094, filed on Aug. 15, 2011. The entirety of the above-mentioned patent application is hereby incorporated by reference herein and made a part of this specification.

### BACKGROUND

1. Technical Field

The disclosure relates to a chip package process and a chip package structure, and more particularly to a stacked type chip package process and a stacked type chip package structure.

2. Description of Related Art

In recent years, technology has rapidly progressed, and the needs of consumers are now not limited to just thinner and smaller products, but further wish for more functions integrated into one device. Thus, mobile phones are no longer solely equipped for mobile telecommunication, but have developed into smart all-around personal assistants to become a camera, a reader, a global positioning system, an e-mail server, and even a high quality projector under any condition according to consumer need. Besides using a mobile phone for communication, entertainment, and business applications, as cloud computing technology matures, users can use a mobile phone to transmit his or her own health condition to a server of a hospital. This way, the user can quickly know the condition of his or her body, and can even directly receive a diagnosis from a doctor on-line. When there is a need for emergency medical attention, a hospital can provide immediate care through the global positioning system, which is an effective device that the government can use to build a home care network.

However, wafer processing will naturally face physical limitations, and so the technology of the process of fabricating high level carriers of a high IO number is striving to be developed. Also, the technology of adopting a system on Chip (SoC) design for integrating heterogeneous functions is also reaching its limits. Thus, many international companies, and research and development institutions agree to the System in Package (SIP) with the benefits of production time and production cost, which continue to support the effectiveness of the semiconductor industry standard to the technology of Moore's Law. Also, there has been a lot of focus on the technology of high integrated 3-dimensional IC packages, and all industries are concentrating on its development, ambitiously investing in the growth of related technology.

However, regarding the capabilities of mass production, 3DIC packages have many technical thresholds. First off, there is the problem of thin wafer handling. When the thickness of a wafer becomes less than 50 micrometers, a solution is required in how to remove film on the backside of a chip without breakage after a wafer to wafer or chip to wafer fabrication process. Also, when the IO number of a component is less than 1000, using deep reactive-ion etching (DRIE) to fabricate through silicon vias (TSV) requires the consideration of production cost. If a laser method is used, whether or not the roughness of the via walls are suitable for implementing a subsequent insulation process must be considered. Finally, regarding the effectiveness of micro-connection assemblies, the thermal bonding capacity of some 3DICs may not be as good as conventional solder processes, and the thermal gradient might easily cause the interface of the micro-connections to have an unbalanced response, raising doubt about long term reliability. In order for 3DICs to effectively be mass produced, it is important to address solutions to the aforementioned problems.

### SUMMARY

The disclosure provides a chip package structure, including a substrate, a chip, an insulating layer, a third patterned conductive layer, and an electronic element. The substrate has a first patterned conductive layer. The chip is disposed on the substrate. A second patterned conductive layer of the chip is bonded to the first patterned conductive layer of the substrate. The chip has a first through hole. The insulation layer is disposed on the chip and filled into the first through hole. The insulating layer has a second through hole. The second through hole passes through the first through hole. The third patterned conductive layer is disposed on the insulating layer and filled into the second through hole to electrically connect to the first patterned conductive layer. The electronic element is disposed on the third patterned conductive layer and electrically connects to the third patterned conductive layer.

The disclosure further provides a chip package structure, including a substrate, a chip, an insulating layer, a third patterned conductive layer, and an electronic element. The substrate has a first patterned conductive layer. The chip is disposed on the substrate. The first patterned conductive layer of the chip faces away from a second patterned conductive layer of the chip. The chip has a first through hole. The insulation layer is disposed on the second patterned conductive layer of the chip and filled into the first through hole. The insulating layer has a second through hole. The second through hole passes through the first through hole and exposes the first patterned conductive layer. The third patterned conductive layer is disposed on the insulating layer and filled into the second through hole to electrically connect the first patterned conductive layer and the second patterned conductive layer. The electronic element is disposed on the third patterned conductive layer and electrically connects to the third patterned conductive layer.

The disclosure also provides a chip package process comprising the following steps. A chip is disposed on a substrate, and the chip has a first through hole. A first patterned conductive layer of the substrate is bonded to a second patterned conductive layer of the chip. An insulating layer is formed on the chip. The insulating layer fills the first through hole. A second through hole passing through the insulating layer is formed. The second through hole passes through the first through hole. A third patterned conductive layer is formed on the insulating layer. The third patterned conductive layer is filled into the second through hole to electrically connect to the first patterned conductive layer. An electronic element is disposed on the third patterned conductive layer, wherein the electronic element is electrically connected to the third patterned conductive layer.

The disclosure further provides a chip package process comprising the following steps. A chip is disposed on a substrate. A second patterned conductive layer of the chip faces away from a first patterned conductive layer of the substrate. A first through hole passing through the chip is formed. An insulting layer is formed on the second patterned conductive layer of the chip. The insulating layer fills the first through hole. A second through hole passing through the insulating layer is formed. The second through hole passes through the first through hole and exposes the first patterned conductive layer. A third patterned conductive layer is formed on the insulating layer. The third patterned conductive layer is filled into the second through hole to electrically connect the second patterned conductive layer and the first patterned conductive layer. An electronic element is disposed on the third patterned conductive layer, wherein the electronic element is electrically connected to the third patterned conductive layer.

Several exemplary embodiments accompanied with figures are described in detail below to further describe the disclosure.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A to FIG. 1H are schematic cross-sectional views illustrating a chip package process according to an exemplary embodiment.

FIG. 2A to FIG. 2I are schematic cross-sectional views illustrating a chip package process according to another exemplary embodiment.

FIG. 3A to FIG. 3I are schematic cross-sectional views illustrating a chip package process according to another exemplary embodiment.

FIG. 4A to FIG. 4I are schematic cross-sectional views illustrating a chip package process according to another exemplary embodiment.

### DETAILED DESCRIPTION

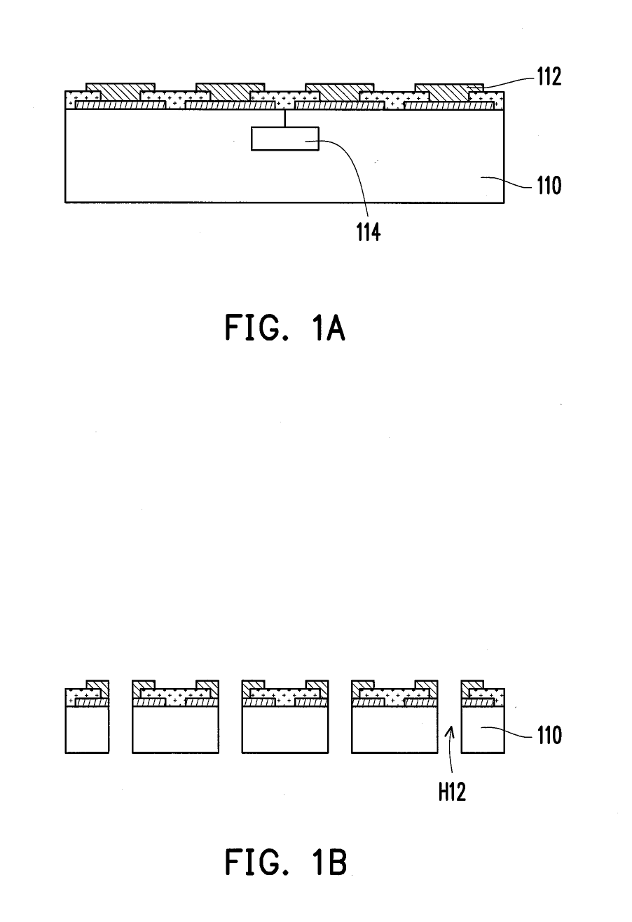

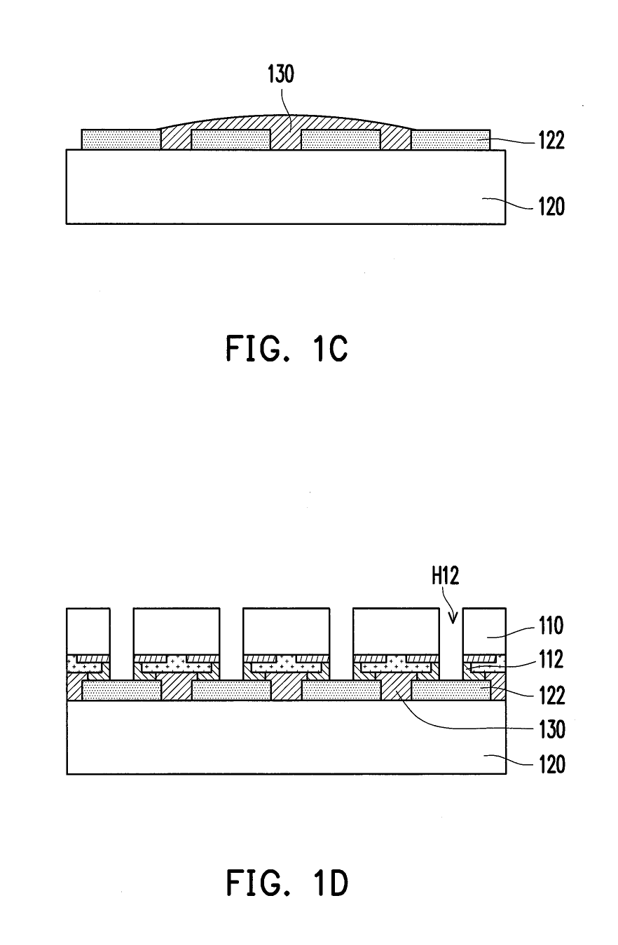

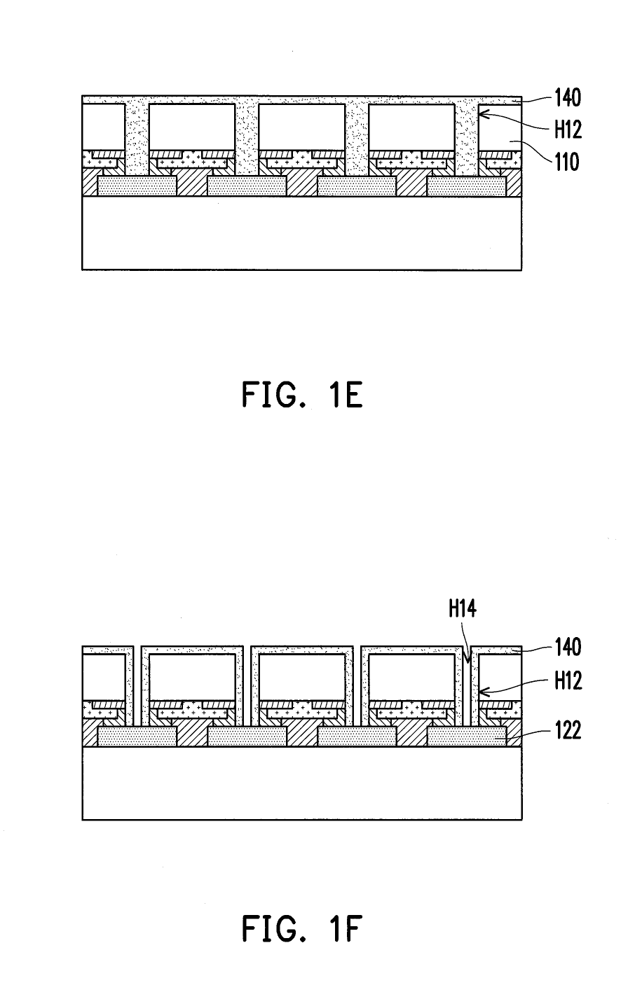

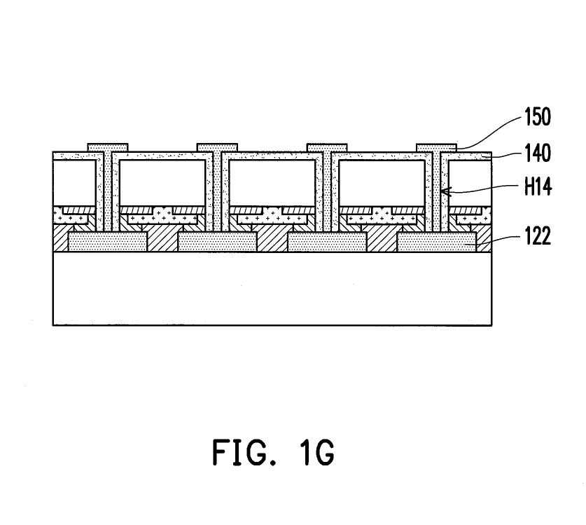

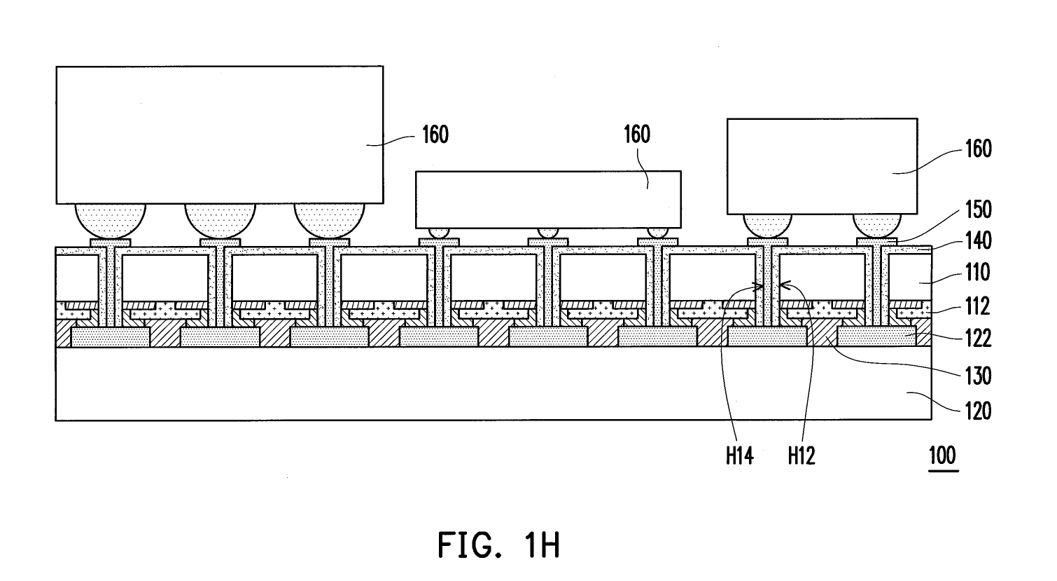

FIG. 1A to FIG. 1H are schematic cross-sectional views illustrating a chip package process according to an exemplary embodiment. Referring to FIG. 1A, the chip package process of the embodiment first prepares a chip 110. The chip 110 has a patterned conductive layer 112. The patterned conductive layer 112 can be a plurality of pads or a combination of a plurality of pads and lines. A function circuit 114 electrically connected to the patterned conductive layer 112 is embedded within the chip 110 of the embodiment. The function circuit 114 is shown with border lines only in FIG. 1A. The function circuit 114 may be a logical circuit, a memory circuit, or any active or passive function circuit, and is formed on a silicon base or the base of another material through a semiconductor process. In other exemplary embodiments, the chip 110 can also simply be a silicon base or a base of another material, and no function circuit is embedded, so only a patterned conductive layer 112 is formed in the surface. Furthermore, when performing the chip package process of the embodiment, the chip 110 can be cut and separated from the wafer, or not be cut and separated.

As shown in FIG. 1B, a thinning process is selectively performed towards the chip 110. In addition, the chip 110 has a through hole H12. The embodiment is described with multiple through holes H12, but can also have only a single through hole H12. The through holes H12 can be formed before or after performing thinning to the chip 110. The method for forming the through holes H12 is, for example, by laser drilling or DRIE. FIG. 1B illustrates cross-sections that go through the through holes H12, and does not represent the chip 110 being cut into multiple parts. In addition, referring to FIG. 1C, a substrate 120 is provided. The substrate 120 has a patterned conductive layer 122. At this point, non-conductive paste 130 can be selectively applied to the surface of the substrate 120 having the patterned conductive layer 122.

Referring to FIG. 1D, the substrate 120 is disposed on the chip 110, so that the patterned conductive layer 122 of the substrate 120 is bonded to the patterned conductive layer 112 of the chip 110. The through holes H12 of the embodiment, for example, pass through the patterned conductive layer 112 and expose the patterned conductive layer 122. When selectively using the non-conductive paste 130, a low process temperature of about 200° C. is enough to stably and quickly bond the chip 110 and the substrate 120. This reduces the problem of remaining thermal stress, and improves the process yield of micro-connections. Micro-connections are defined as when the distances between the connections are smaller than or equal to 50 micrometers. On the other hand, the patterned conductive layer 122 and the patterned conductive layer 112 can be bonded through anisotropic conductive film (ACF), silver glue, or glue of other materials. The bonding method can also be bonding methods such as metal welding, metal eutectic bonding, and metal diffusing.

In other embodiments, the through holes H12 of the chip 110 can be formed after the patterned conductive layer 112 of the substrate 120 and the patterned conductive layer 112 of the chip 110 are bonded.

Referring to FIG. 1E, an insulating layer 140 is formed on the chip 110. The insulating layer 140 fills the through holes H12. The method of forming the insulating layer 140 is, for example, by directly compressing the insulating material on the chip 110.

Referring to FIG. 1F, through holes H14 passing through the insulating layer 140 are formed. The through holes H14 pass through the through holes H12. The through holes H14 of the embodiment expose the patterned conductive layer 122. The method for forming the through holes H14 is, for example, by laser drilling.

Referring to FIG. 1G, a patterned conductive layer 150 is formed on the insulting layer 140. The patterned conductive layer 150 is filled into the through holes H14 to electrically connect to the patterned conductive layer 122.

Referring to FIG. 1H, an electronic element 160 is disposed on the patterned conductive layer 150, and the electronic element 160 is electrically connected to the patterned conductive layer 150. The electronic element 160 can be a variety of active or passive elements. The embodiment is described with multiple electronic elements 160, but can also have only a single electronic element 160. The electronic element 160 is electrically connected to the patterned conductive layer 150 through, for example, wire bonding, general bumps, or micro-bumps. Micro-bumps are defined as when the distance between two bumps are smaller than or equal to 50 micrometers. Up to here, the chip package process of the embodiment is basically complete.

Next, referring to FIG. 1H, a chip package structure 100 of an exemplary embodiment of the disclosure includes a substrate 120, a chip 110, an insulating layer 140, a patterned conductive layer 150, and an electronic element 160. The substrate 120 has a patterned conductive layer 122. The chip 110 is disposed on the substrate 120. A patterned conductive layer 112 of the chip 110 is bonded to the patterned conductive layer 122 of the substrate 120. The chip 110 has a through hole H12. The insulation layer 140 is disposed on chip 110 and filled into the through hole H12. The insulating layer 140 has a through hole H14. The through hole H14 passes through the through hole H12. The patterned conductive layer 150 is disposed on the insulating layer 140 and filled into the through hole H14 to electrically connect to the patterned conductive layer 122. The electronic element 160 is disposed on the patterned conductive layer 150 and electrically connects to the patterned conductive layer 150. The above has described the basic structure of the chip package structure 100 of the embodiment. More detail can be seen in descriptions of FIG. 1A to FIG. 1G.

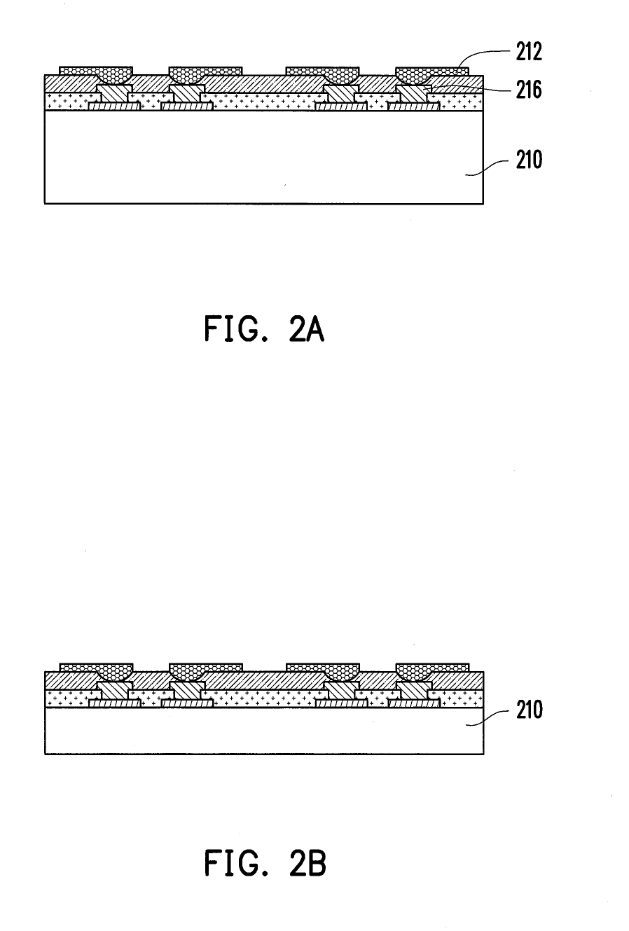

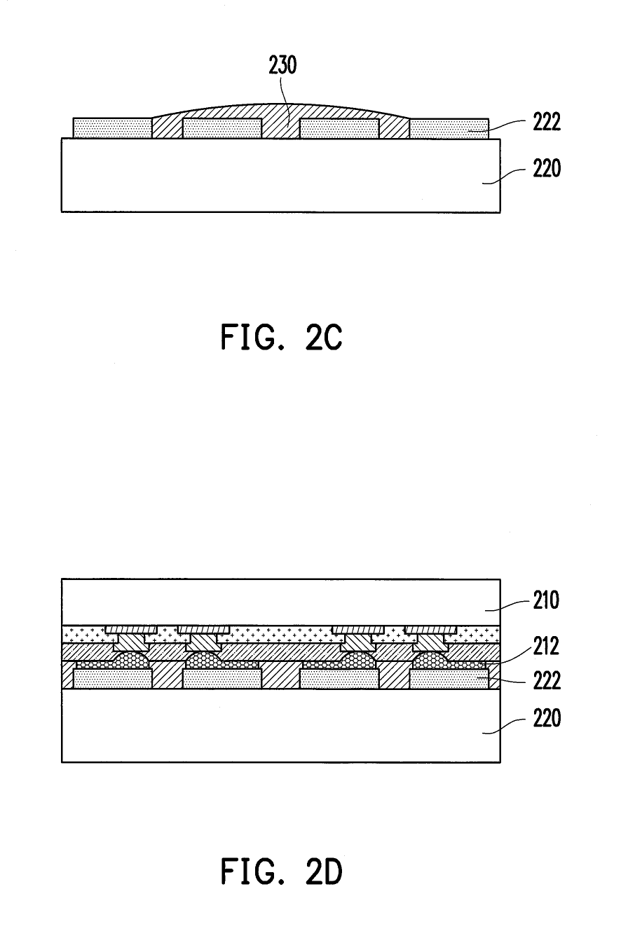

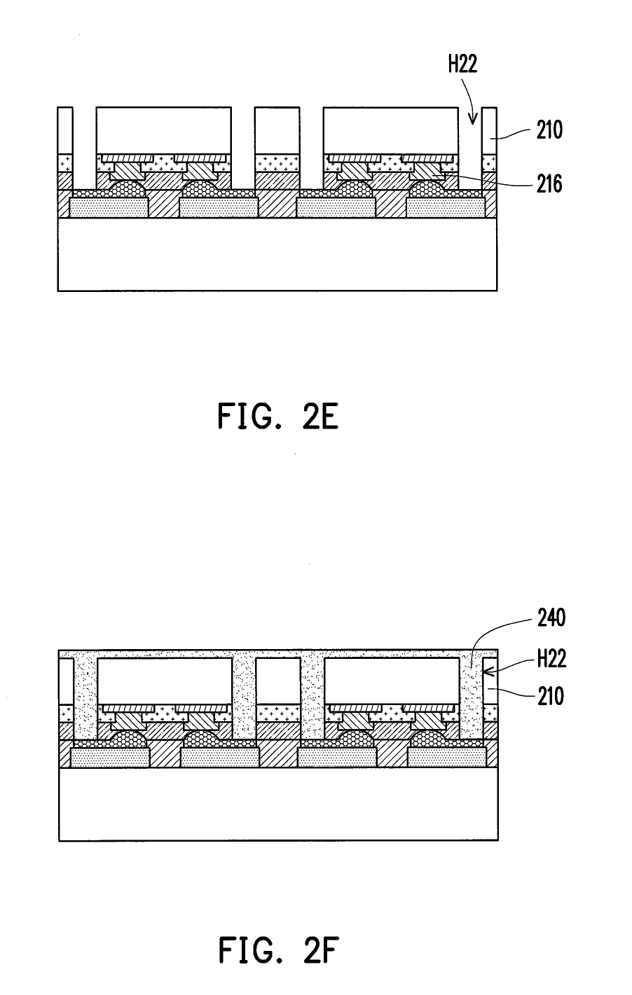

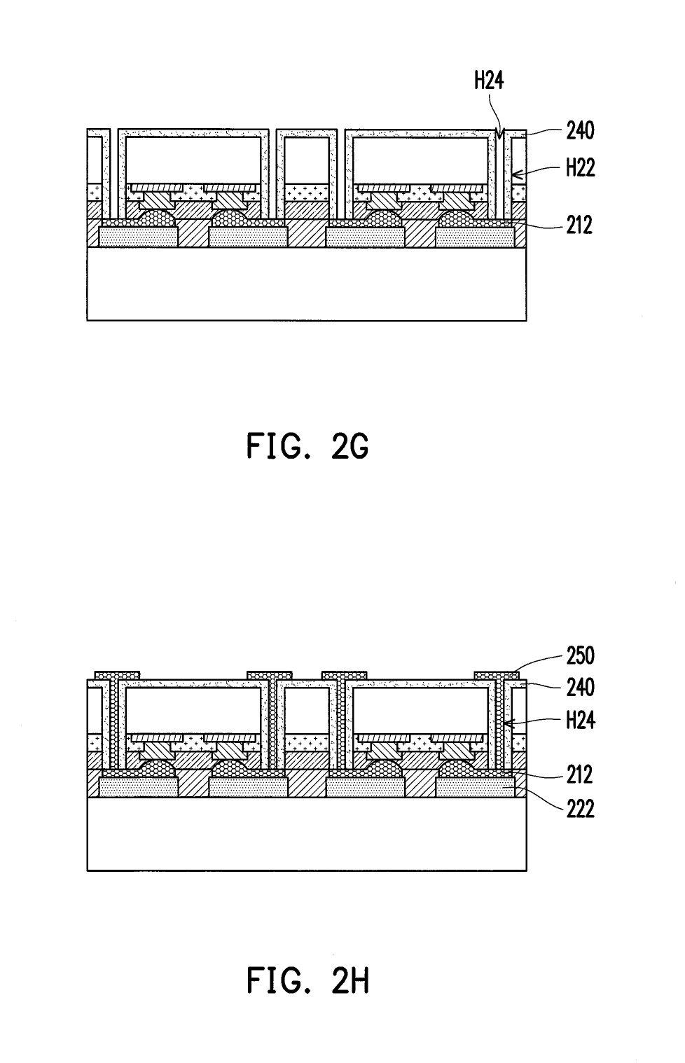

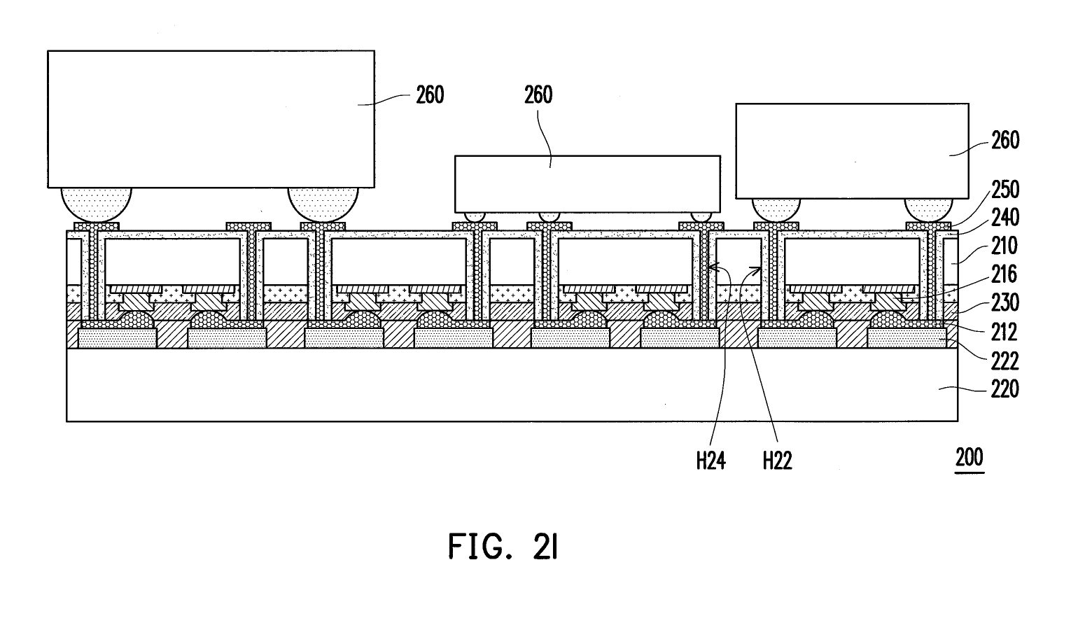

FIG. 2A to FIG. 2I are schematic cross-sectional views illustrating a chip package process according to another exemplary embodiment. The following will mainly describe the differences between the chip package process of the embodiment and the chip package process of FIG. 1A to FIG. 1H. Referring to FIG. 2A, the bottom of a patterned conductive layer 212 of a chip 210 of the embodiment further includes a redistribution layer 216. The redistribution layer 216 can be a single circuit layer or a combination of multiple circuit layers, and insulating layers are disposed between each circuit layer. The redistribution layer 216 is electrically connected to the patterned conductive layer 212. The goal of the redistribution layer 216 is to arrange the pads in suitable locations better for packaging. Referring to FIG. 2B, the chip 210 is thinned. Referring to FIG. 2C, non-conductive paste 230 can be selectively applied to the surface of the substrate 220 having the patterned conductive layer 222. Referring to FIG. 2D, the substrate 220 is disposed on the chip 210, so that the patterned conductive layer 222 of the substrate 220 is bonded to the patterned conductive layer 212 of the chip 210.

Referring to FIG. 2E, through holes H22 passing through the insulating layer 210 are formed. The through holes H22 avoid the circuit of the redistribution layer 216. Referring to FIG. 2F, an insulating layer 240 is formed on the chip 210. The insulating layer 240 fills the through holes H22. Referring to FIG. 2G, through holes H24 passing through the insulating layer 240 are formed. The through holes H24 pass through the through holes H22. The through holes H24 of the embodiment expose the patterned conductive layer 212. Referring to FIG. 2H, a patterned conductive layer 250 is formed on the insulting layer 240. The patterned conductive layer 250 is filled into the through holes H24 to electrically connect to the patterned conductive layer 212. The patterned conductive layer 250 is electrically connected to the patterned conductive layer 222 through the patterned conductive layer 212.

Referring to FIG. 2I, an electronic element 260 is disposed on the patterned conductive layer 250, and the electronic element 260 is electrically connected to the patterned conductive layer 250. Up to here, the chip package process of the embodiment is basically completed. The chip package structure 200 of the embodiment is similar to the chip package structure 100 of FIG. 1H, and the difference is described in the descriptions of FIG. 2A to FIG. 2H. In addition, the difference between the through holes H14 of the chip package structure 100 of FIG. 1H and the through holes H24 of the chip package structure 200 of FIG. 2I is whether or not the patterned conductive layer is passed through. However, a single chip package structure can simultaneously have both types of through holes.

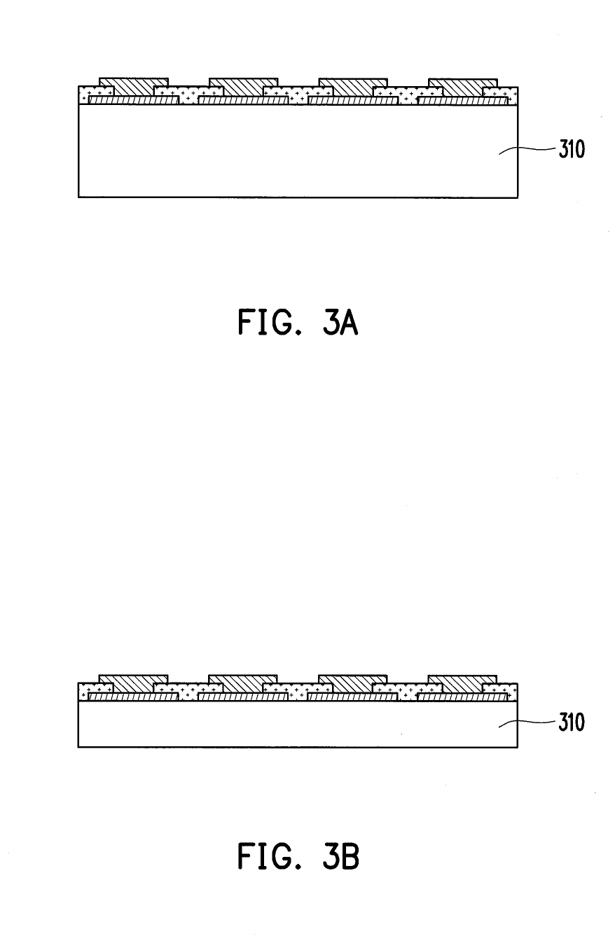

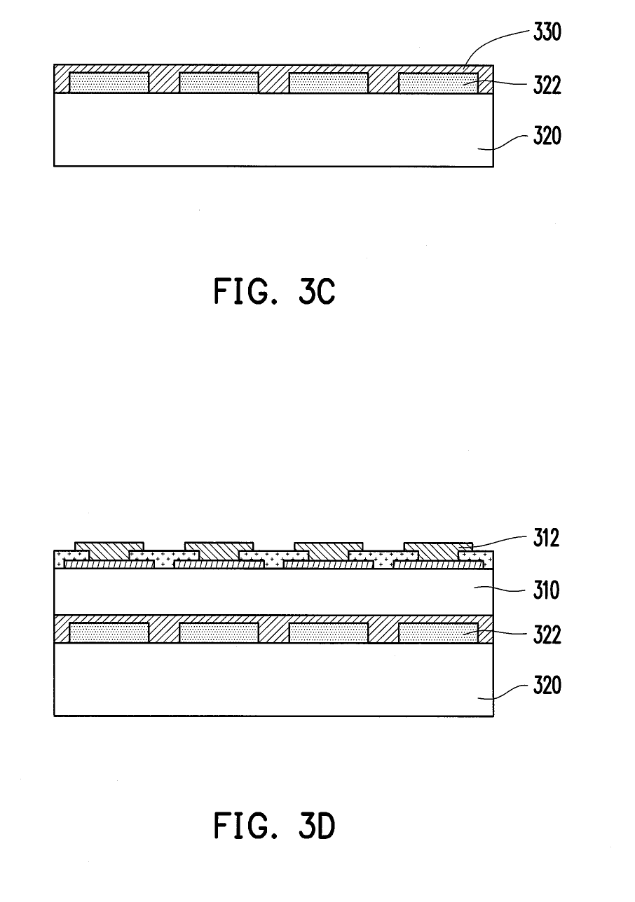

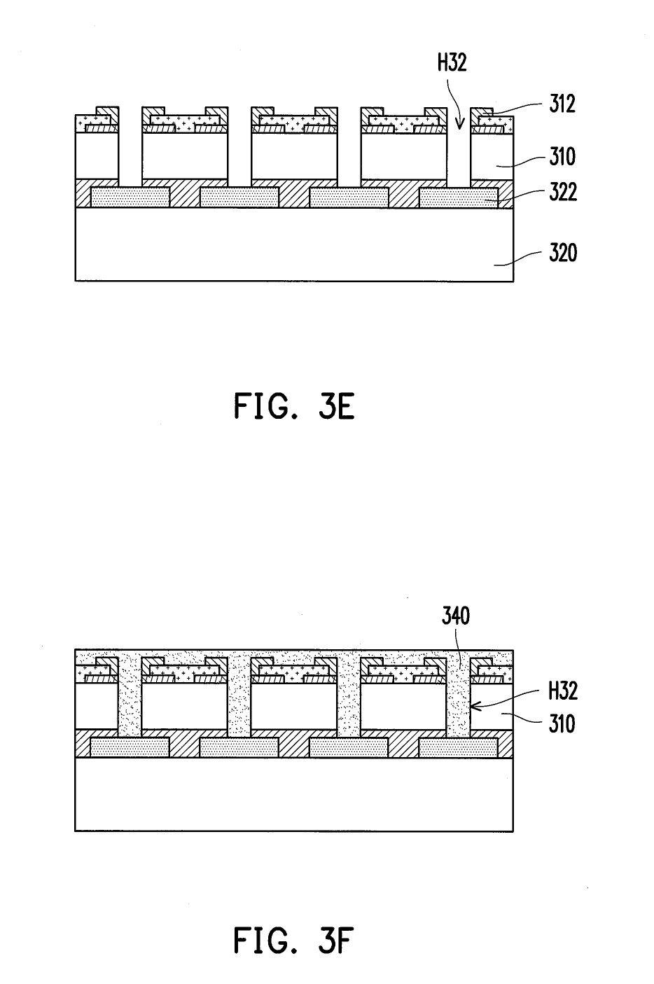

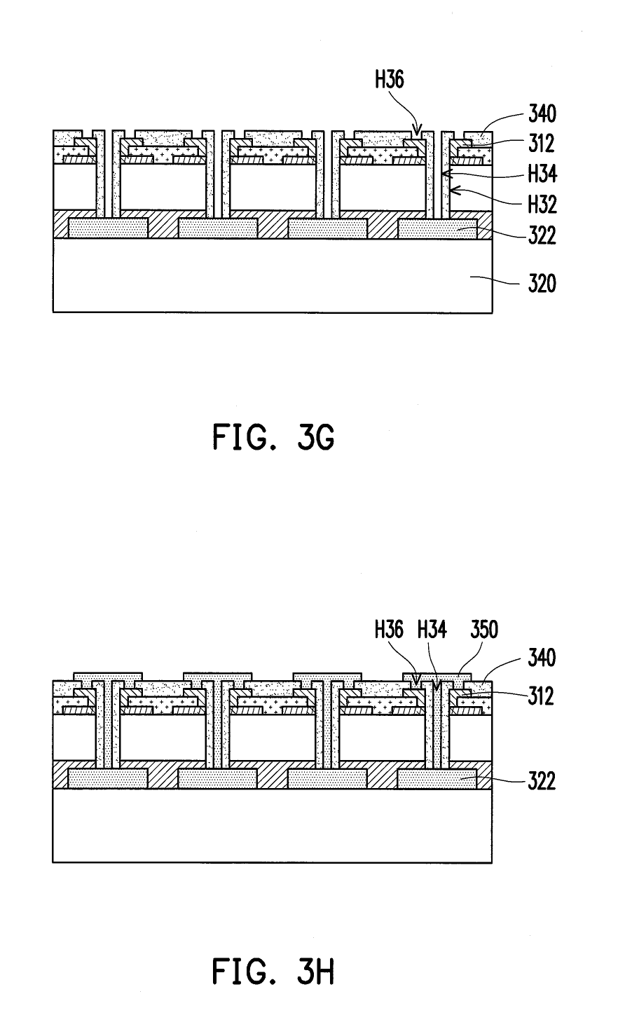

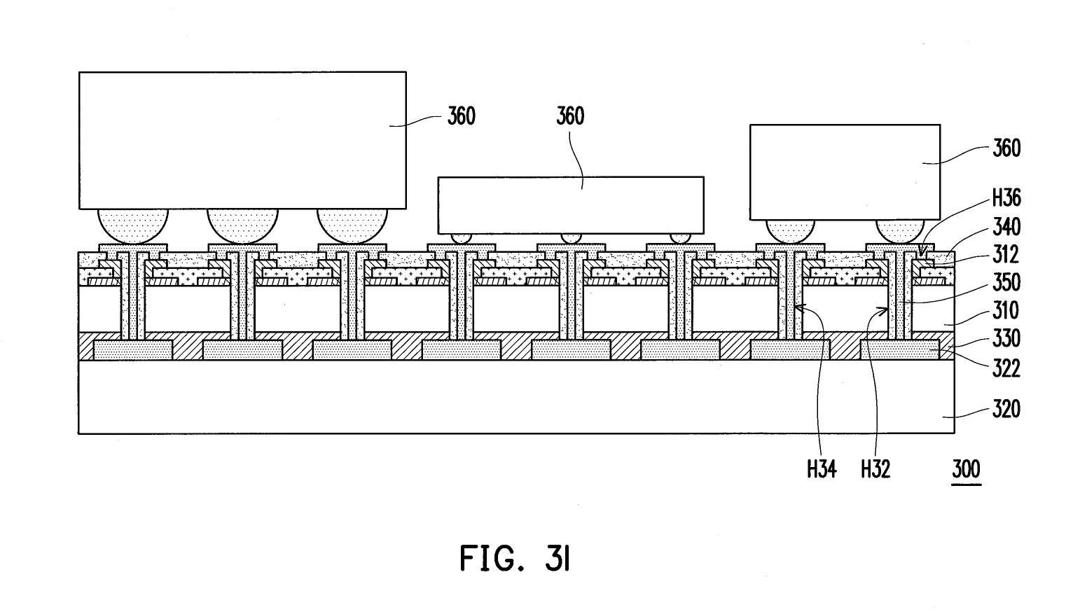

FIG. 3A to FIG. 3I are schematic cross-sectional views illustrating a chip package process according to another exemplary embodiment. The following will mainly describe the differences between the chip package process of the embodiment and the chip package process of FIG. 1A to FIG. 1H. Referring to FIG. 3A, a chip 310 is provided. Referring to FIG. 3B, the chip 310 is thinned. Referring to FIG. 3C, non-conductive paste 330 can be selectively applied to the surface of the substrate 320 having a patterned conductive layer 322. Referring to FIG. 3D, the chip 310 is disposed on the substrate 320. A patterned conductive layer 312 of the chip 310 faces away from the patterned conductive layer 322 of the substrate 320. In other words, the chip 310 contacts the substrate 320 with a face that does not have the patterned conductive layer 312.

Referring to FIG. 3E, through holes H32 passing through the chip 310 are formed. The through holes H32, for example, pass through the patterned conductive layer 312 and expose the patterned conductive layer 322. Referring to FIG. 3F, an insulating layer 340 is formed on the chip 310. The insulating layer 340 fills the through holes H32. Referring to FIG. 3G, through holes H34 passing through the insulating layer 340 are formed. The through holes H34 pass through the through holes H32 and expose the patterned conductive layer 322. In addition, through holes H36 passing through the insulating layer 340 can be selectively formed when forming the through holes H34. The through holes H34 and the through holes H36 can be synchronously formed or formed in two steps. The through holes H36 expose the patterned conductive layer 312. Referring to FIG. 3H, a patterned conductive layer 350 is formed on the insulting layer 340. The patterned conductive layer 350 is filled into the through holes H34 and electrically connects the patterned conductive layer 322 and the patterned conductive layer 312. The patterned conductive layer 350 of the embodiment is filled into the through holes H36 to electrically connect to the patterned conductive layer 312.

Referring to FIG. 3I, an electronic element 360 is disposed on the patterned conductive layer 350, and the electronic element 360 is electrically connected to the patterned conductive layer 350. Up to here, the chip package process of the embodiment is basically completed. The chip package structure 300 of the embodiment is similar to the chip package structure 100 of FIG. 1H, and the difference is described in the descriptions of FIG. 3A to FIG. 3H.

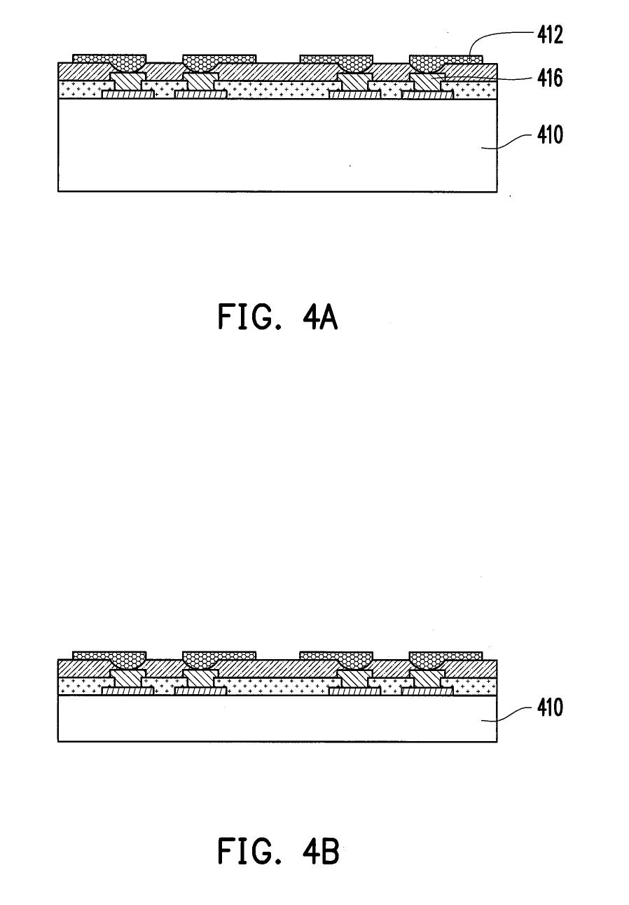

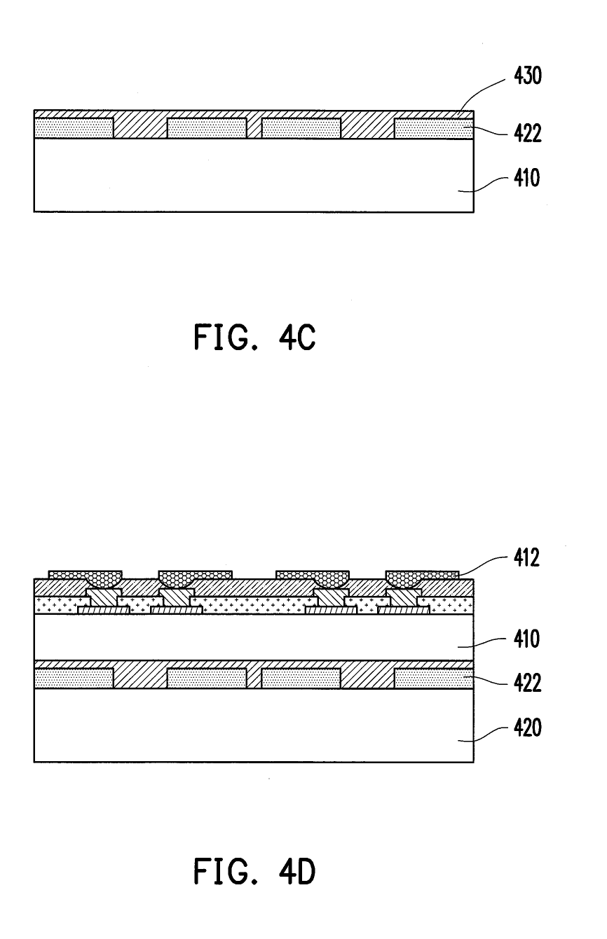

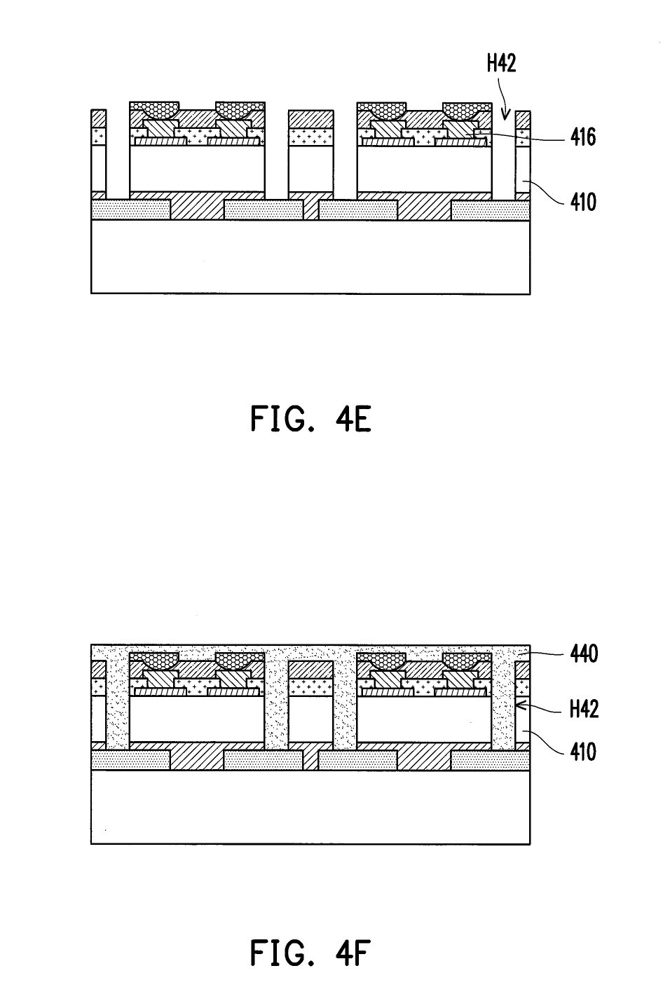

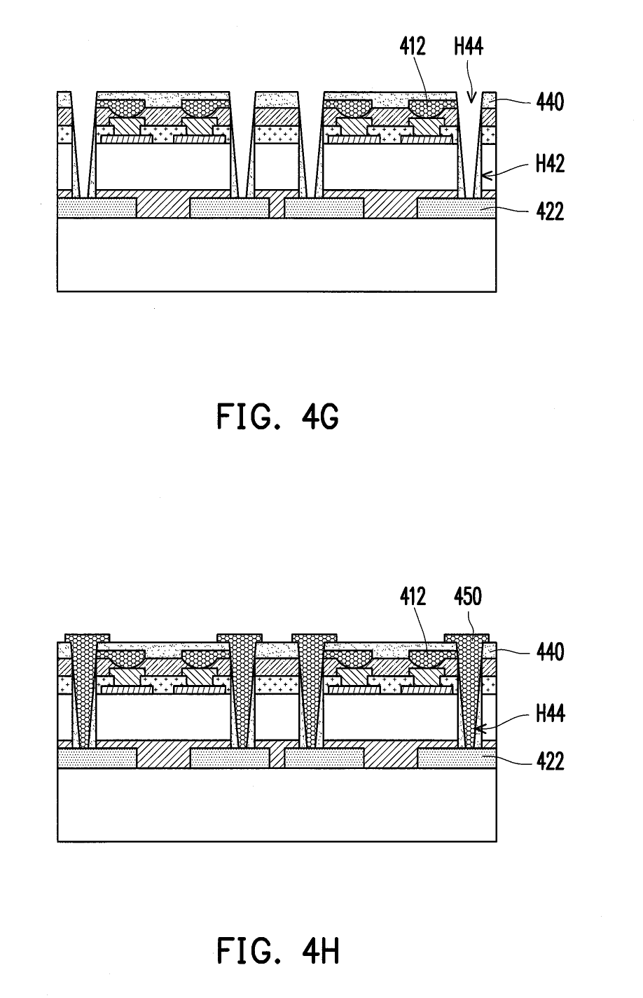

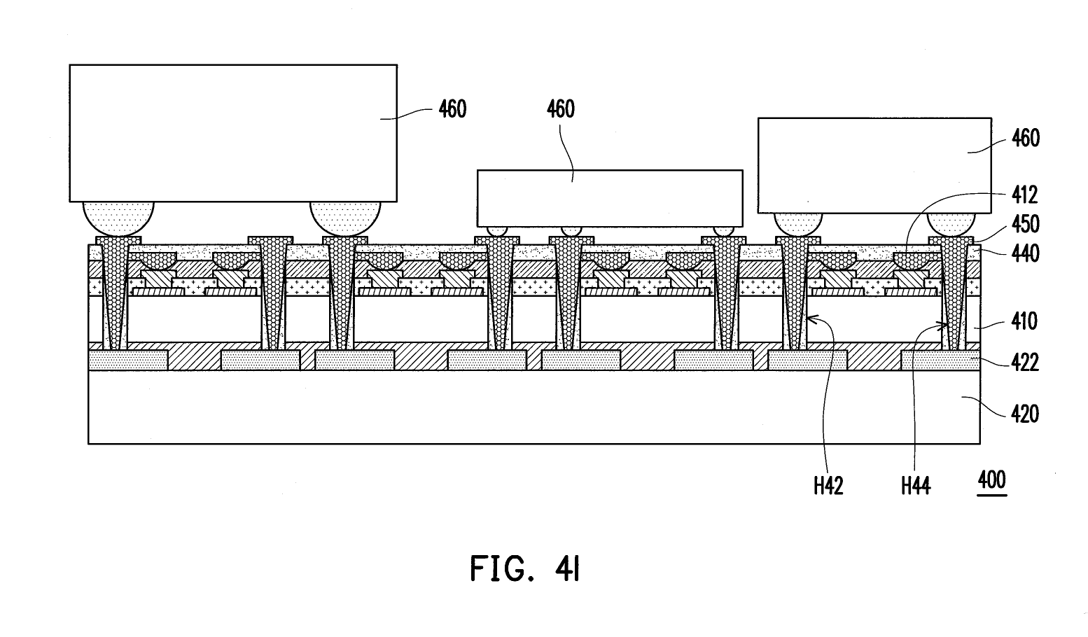

FIG. 4A to FIG. 4I are schematic cross-sectional views illustrating a chip package process according to another exemplary embodiment. The following will mainly describe the differences between the chip package process of the embodiment and the chip package process of FIG. 3A to FIG. 3I. Referring to FIG. 4A, the bottom of a patterned conductive layer 412 of a chip 410 of the embodiment further includes a redistribution layer 416. The redistribution layer 416 is electrically connected to the patterned conductive layer 412. Referring to FIG. 4B, the chip 410 is thinned. Referring to FIG. 4C, non-conductive paste 430 can be selectively applied to the surface of the substrate 420 having a patterned conductive layer 422. Referring to FIG. 4D, the substrate 420 is disposed on the chip 410, and the patterned conductive layer 412 of the chip 410 faces away from the patterned conductive layer 422 of the substrate 420.

Referring to FIG. 4E, through holes H22 passing through the insulating layer 410 are formed. The through holes H42 avoid the circuit of the redistribution layer 416. Referring to FIG. 4F, an insulating layer 440 is formed on the chip 410. The insulating layer 440 fills the through holes H42. Referring to FIG. 4G, through holes H44 passing through the insulating layer 440 are formed. The through holes H44 pass through the through holes H42. The through holes H44 of the embodiment expose the patterned conductive layer 422, and the patterned conductive layer 412 is exposed in the walls of the through holes H44. Referring to FIG. 4H, a patterned conductive layer 450 is formed on the insulting layer 440. The patterned conductive layer 450 is filled into the through holes H44 and electrically connects the patterned conductive layer 422 and the patterned conductive layer 412.

Referring to FIG. 4I, an electronic element 460 is disposed on the patterned conductive layer 450, and the electronic element 460 is electrically connected to the patterned conductive layer 450. Up to here, the chip package process of the embodiment is basically completed. The chip package structure 400 of the embodiment is similar to the chip package structure 300 of FIG. 3, and the difference is described in the descriptions of FIG. 4A to FIG. 4H. In addition, the difference between the through holes H34 of the chip package structure 300 of FIG. 3I and the through holes H44 of the chip package structure 400 of FIG. 4I is whether or not the patterned conductive layer is passed through. However, a single chip package structure can simultaneously have both types of through holes.

To sum up, in the chip package structure and the chip package process of the disclosure, a chip serving as an intermediate carrier can be embedded between a substrate and an insulating layer, thus reducing the overall thickness. In addition, the bonding process of the chip and the substrate does not require a high process temperature, which improves the feasibility and reliability of the utilization of micro-connections. Also, the signal transmission path is reduced, improving the electrical characteristics of the chip package structure.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A chip package process, the process comprising:
disposing a chip onto a substrate, wherein a first patterned conductive layer of the substrate is bonded to a second patterned conductive layer of the chip, and the chip has a first through hole;
forming an insulating layer on the chip, wherein the insulating layer fills the first through hole;
forming a second through hole passing through the insulating layer, wherein the second through hole passes through the first through hole;
forming a third patterned conductive layer on the insulating layer, wherein the third patterned conductive layer fills the second through hole to electrically connect to the first patterned conductive layer; and
disposing an electronic element on the third patterned conductive layer, wherein the electronic element is electrically connected to the third patterned conductive layer.

2. The chip package process as claimed in claim 1, further comprising thinning the chip before the chip is disposed onto the substrate.

3. The chip package process as claimed in claim 1, further comprising applying a non-conductive paste to the substrate before the chip is disposed onto the substrate.

4. The chip package process as claimed in claim 1, wherein the step of forming the first through hole comprises causing the first through hole to pass through the second patterned conductive layer.

5. The chip package process as claimed in claim 1, wherein the step of forming the second through hole comprises causing the second through hole to expose the first patterned conductive layer.

6. The chip package process as claimed in claim 1, wherein a bottom of the second patterned conductive layer of the chip further comprises a redistribution layer.

7. The chip package process as claimed in claim 6, wherein the step of forming the first through hole comprises causing the first through hole to avoid a circuit of the redistribution layer.

8. The chip package process as claimed in claim 1, wherein the step of forming the second through hole comprises causing the second through hole to expose the second patterned conductive layer.

9. The chip package process as darned in claim 1, wherein the third patterned conductive layer is electrically connected to the first patterned conductive layer through the second patterned conductive layer.

10. A chip package process, the process comprising:
disposing a chip onto a substrate, wherein a second patterned conductive layer of the chip faces away from a first patterned conductive layer of the substrate;
forming a first through hole passing through the chip;
forming an insulating layer on the second patterned conductive layer of the chip, wherein the insulating layer fills the first through hole;
forming a second through hole passing through the insulating layer, wherein the second through hole passes through the first through hole and exposes the first patterned conductive layer;
forming a third patterned conductive layer on the insulating layer, wherein the third patterned conductive layer fills the second through hole and electrically connects the second patterned conductive layer and the first patterned conductive layer; and
disposing an electronic element on the third patterned conductive layer, wherein the electronic element is electrically connected to the third patterned conductive layer.

11. The chip package process as claimed in claim 10, further comprising thinning the chip before the chip is disposed onto the substrate.

12. The chip package process as claimed in claim 10, further comprising applying a non-conductive paste to the substrate before the chip is disposed onto the substrate.

13. The chip package process as claimed in claim 10, wherein the step of forming the first through hole comprises causing the first through hole to pass through the second patterned conductive layer.

14. The chip package process as claimed in claim 10, wherein a third through hole passing through the insulating layer is formed when the second through hole is formed, the third through hole exposes the second patterned conductive layer, and the third patterned conductive layer fills the third through hole.

15. The chip package process as claimed in claim 10, wherein a bottom of the second patterned conductive layer of the chip further comprises a redistribution layer.

16. The chip package process as claimed in claim 15, wherein the step of forming the first through hole comprises causing the first through hole to avoid a circuit of the redistribution layer.

17. The chip package process as claimed in claim 10, wherein the step of forming the second through hole comprises causing the second patterned conductive layer to be exposed in a wall of the second through hole.

18. A chip package structure, comprising:
a substrate, having a first patterned conductive layer;
a chip, disposed on the substrate, wherein a second patterned conductive layer of the chip is bonded to the first patterned conductive layer of the substrate, and the chip has a first through hole;
an insulting layer, disposed on the chip and filled into the first through hole, wherein the insulating layer comprises a second through hole, and the second through hole passes through the first through hole;
a third patterned conductive layer, disposed on the insulating layer and filled into the second through hole to electrically connect to the first patterned conductive layer; and
an electronic element, disposed on the third patterned conductive layer, wherein the electronic element is electrically connected to the third patterned conductive layer.

19. The chip package structure as claimed in claim 18, further comprising a non-conductive paste, disposed between the chip and the substrate.

20. The chip package structure as claimed in claim 18, wherein the first through hole passes through the second patterned conductive layer.

21. The chip package structure as claimed in claim 18, wherein the second through hole exposes the first patterned conductive layer.

22. The chip package structure as claimed in claim 18, wherein a bottom of the second patterned conductive layer of the chip further comprises a redistribution layer.

23. The chip package structure as claimed in claim 22, wherein the first through hole avoids a circuit of the redistribution layer.

24. The chip package structure as claimed in claim 18, wherein the second through hole exposes the second patterned conductive layer.

25. The chip package structure as darned in claim 18, wherein the third patterned conductive layer is electrically connected to the first patterned conductive layer through the second patterned conductive layer.

26. The chip package structure as claimed in claim 18, wherein a function circuit electrically connected to the second patterned conductive layer is embedded in the chip.

27. A chip package structure, comprising:
a substrate, having a first patterned conductive layer;
a chip, disposed on the substrate, wherein a second patterned conductive layer of the chip faces away from the first patterned conductive layer of the substrate, and the chip has a first through hole;
an insulting layer, disposed on the second patterned conductive layer of the chip and filled into the first through hole, wherein the insulating layer comprises a second through hole, and the second through hole passes through the first through hole and exposes the first patterned conductive layer;
a third patterned conductive layer, disposed on the insulating layer and filled into the second through hole to electrically connect the first patterned conductive layer and the second patterned conductive layer; and
an electronic element, disposed on the third patterned conductive layer, wherein the electronic element is electrically connected to the third patterned conductive layer.

28. The chip package structure as claimed in claim 27, further comprising a non-conductive paste, disposed between the chip and the substrate.

29. The chip package structure as claimed in claim 27, wherein the first through hole passes through the second patterned conductive layer.

30. The chip package structure as claimed in claim 27, wherein the insulting layer further comprises a third through hole, the third through hole exposes the second patterned conductive layer, and the third patterned conductive layer fills the third through hole.

31. The chip package structure as claimed in claim 27, wherein a bottom of the second patterned conductive layer of the chip further comprises a redistribution layer.

32. The chip package structure as claimed in claim 31, wherein the first through hole avoids a circuit of the redistribution layer.

33. The chip package structure as claimed in claim 27, wherein the second patterned conductive layer is exposed in a wall of the second through hole.

34. The chip package structure as claimed in claim 27, wherein a function circuit electrically connected to the second patterned conductive layer is embedded in the chip.
